(19) United States
(12) Patent Application Publication
(10) Pub. No.: US 2026/0145946 A1
(43) Pub. Date: May 28, 2026

(54) CARBON NANOTUBE HYBRID MATERIAL

(71) Applicant: BIRLA CARBON U.S.A., INC., Marietta, GA (US)

(72) Inventors: Arati Varma, Navi Mubai (IN); Amol Niphade, Navi Mubai (IN); Bhupendra Magare, Navi Mubai (IN)

(21) Appl. No.: 19/123,302

(22) PCT Filed: Oct. 26, 2023
(86) PCT No.: PCT/US2023/077830

§ 371 Date: Apr. 22, 2025

Related U.S. Application Data
(60) Provisional application No. 63/431,368, filed on Dec. 9, 2022.

(30) Foreign Application Priority Data
Oct. 26, 2022 (IN) 202211060980

(51) Int. Cl. C01B 32/162; B01J 21/18; B01J 23/755; B01J 23/882; B01J 37/00; B01J 37/18; C23C 16/26

(52) U.S. Cl. CPC C01B 32/162; B01J 21/18; B01J 23/755; B01J 23/882; B01J 37/009; B01J 37/18; C23C 16/26; C01P 2002/82; C01P 2004/03; C01P 2004/04; C01P 2004/13

(57) ABSTRACT

Methods for catalytically growing carbon nanotubes on carbonaceous substrates and hybrid materials prepared by the methods.

### CROSS-REFERENCE TO RELATED APPLICATIONS

This application claims priority to Indian Patent Application number 202211060980, filed Oct. 26, 2022, and U.S. Provisional Application No. 63/431,368, filed Dec. 9, 2022, both of which are incorporated into this application by reference.

### BACKGROUND

Carbon black is a form of amorphous carbon that is used as a pigment or as a reinforcement filler in rubber and plastic products. Because of its graphitic crystallite nature, it imparts some electrostatic properties to non-conducting materials and thus finds application in many areas like conducting polymers, inks, paints, and antistatic coatings. For some applications, another form of nanostructured carbon such as carbon nanotubes (CNTs) can be combined with carbon black to improve conductivity, mechanical properties, and chemical strength of the end product.

CNTs are one atom thick sheets of carbon rolled to form a cylinder having a diameter in the nanometer range and a length up to a few microns. Owing to their superior chemical, mechanical, thermal, and optical properties, CNTs can be used in composites and microelectronics. However, due to cost, it can be desirable to optimize CNT loading to maintain a material balance between performance and cost. The performance of CNT composite materials generally depends on homogeneous mixing of different nanostructures in the vehicle matrix.

Existing methods of physical mixing often lead to inhomogeneous dispersions resulting in only marginal impacts on end properties. Additionally, mixing of two nanoscale ingredients in a vehicle matrix may lead to safety hazards while handling. It would be beneficial to incorporate CNTs on the surface of a carbon structure to get a single synergic material.

### SUMMARY

This disclosure relates to an improved method to grow CNTs onto a catalyzed carbonaceous substrate using a variety of feed gases. Creating the disclosed composite material involves generating catalyzed carbon as a support for the growth of CNTs onto the support. The method utilizes a green approach by utilizing a biosource such as lignin or a suitable water-soluble lignin derivative to synthesize the catalyzed carbon without the use of organic solvent. By contrast, many existing wet impregnation methods often use harsh acidic conditions, expensive surfactants, or require multi-step processing to uniformly disperse a catalyst over a carbon support. The existing methods are either expensive or tedious unlike the disclosed method.

In one aspect, the method for making the carbon nanotube hybrid material comprises: (a) dispersing a carbonaceous substrate in a medium comprising water and one or more of: (i) lignin and a first base: or (ii) a water-soluble lignin derivative: where the medium is free of organic solvent and non-lignin derived surfactants: (b) contacting the medium with a metal salt and a second base: (c) forming catalytic sites on the carbonaceous substrate from the metal salt to provide a catalyzed carbonaceous substrate; and (d) exposing the catalyzed carbonaceous substrate to a carbon-containing gas to grow carbon nanotubes on the catalyzed carbonaceous substrate.

In a further aspect, the method comprises: (a) dispersing a carbonaceous substrate in a medium comprising water and one or more of: (i) lignin and a first base; or (ii) a water-soluble lignin derivative: (b) contacting the medium with a metal salt and a second base: (c) obtaining a solid from the medium, the solid comprising the carbonaceous substrate having the metal salt loaded thereon: (d) calcining the solid to convert the metal salt to a metal oxide; (e) reducing the metal oxide to its corresponding elemental metal to form a catalyzed carbonaceous substrate; and (f) exposing the catalyzed carbonaceous substrate to a carbon-containing gas to grow carbon nanotubes on the catalyzed carbonaceous substrate.

Also described are carbon nanotube hybrid materials made by any of the disclosed methods.

### BRIEF DESCRIPTION OF THE DRAWINGS

The foregoing summary, as well as the following description of the disclosure, is better understood when read in conjunction with the appended drawings. For the purpose of illustrating the disclosure, the drawings illustrate some, but not all, alternative embodiments. This disclosure is not limited to the precise arrangements and instrumentalities shown. The following figures, which are incorporated into and constitute part of the specification, assist in explaining the principles of the disclosure.

FIGS. 1A-C show SEM images of the hybrid material made from a nickel catalyst deposited on a Raven PFEB (Birla Carbon, Marietta GA. USA) using carbon monoxide (CO, H₂ and N₂) as feed gas (FIG. 1A: 500 nm scale, FIG. 1B: 2 μm scale, FIG. 1C: 10 μm scale).

FIG. 2 is a Raman spectrum of the hybrid material made from a nickel catalyst deposited on a Raven PFEB substrate and corresponding Ia/Ig ratio of 1.01.

FIGS. 3A-C show SEM images of exemplary hybrid material made from a nickel catalyst deposited on a Raven PFEB, hybrid material made from a nickel and cobalt catalyst deposited on a Raven PFEB, and hybrid material made from cobalt molybdanum catalyst deposited on a Raven PFEB, with HRTEM blown up inserts showing carbon nanotube morphologies (FIG. 3A: 2 μm scale, FIG. 3B: 5 μm scale, FIG. 3C: 2 μm scale).

FIG. 4 shows a HRTEM image of a hybrid material made from nickle catalyst deposited on Raven PFEB, using ethylene (ethylene, H₂, and N₂) as the feed gas (Example 2). (FIG. 4 10 nm scale).

FIG. 5 shows an SEM image of a hybrid material made from Ni catalyst deposited on graphite, using carbon monoxide (CO, H₂, and N₂) as the feed gas (Example 3). (FIG. 5 10 μm scale).

FIG. 6 shows a TEM image of a carbon-CNT hybrid material prepared on Ni-supported Raven PFEB, using a water soluble derivative of lignin, and ethylene (ethylene, H₂, and N₂) as the feed gas (Example 4) (FIG. 6 20 nm scale).

### DETAILED DESCRIPTION

One aspect of the method comprises the following steps: (a) dispersing a carbonaceous substrate in a medium comprising water and one or more of: (i) lignin and a first base: or (ii) a water-soluble lignin derivative: (b) contacting the medium with a metal salt and a second base; (c) forming catalytic sites on the carbonaceous substrate from the metal salt to provide a catalyzed carbonaceous substrate; and (d) exposing the catalyzed carbonaceous substrate to a carbon-containing gas to grow carbon nanotubes on the catalyzed carbonaceous substrate.

One advantage of the method is that the medium can be free of organic solvent and non-lignin derived surfactants. In general, because the process involves water-soluble metal salts, an organic solvent is not required. Specific examples of organic solvents that are unnecessary include alcohols, such as ethanol, propanol, isopropyl alcohol, and the like, in addition to any other volatile organic solvents such as dichloromethane, chloroform, among others known to the skilled artisan. In some aspects, the method as a whole does not involve the use of an organic solvent, i.e., an organic solvent is not used in any step of the process.

Another advantage of the method is that it can avoid the use of non-lignin derived surfactants, and thus is environmentally friendly and sustainable. For example, the medium can be free of non-lignin derived non-ionic surfactants, non-lignin derived zwitterion surfactants, non-lignin derived cationic or amphoteric surfactants. In a specific example, the medium can be free of Triton surfactants including Triton-X-100.

The method is suitable for a variety of carbonaceous substrates. Examples include natural graphite, synthetic graphite, graphene, carbon black, carbon fiber, or activated carbon. In one aspect, the carbonaceous substrate is carbon black. A specific example is Raven PFEB carbon black (Birla Carbon, Marietta GA, USA). In another aspect, the carbonaceous substrate is graphite.

In general, the first base can be any base suitable to provide a medium pH ranging from 8 to 12. Suitable first bases include an ammonia, carbonate, bicarbonate, or hydroxide base. Specific examples include sodium hydroxide, ammonium bicarbonate, and potassium hydroxide.

When a water-soluble lignin derivative is used, such as anionic lignin derivatives, the first base is not needed to dissolve the lignin derivative in the medium. Examples of suitable anionic lignin derivatives include lignosulfonates, which are generally water-soluble anionic polyelectrolyte polymers and byproducts from the production of wood pulp using sulfite pulping. With water-soluble lignin derivatives, while the first base is not needed to dissolve the derivative in the aqueous medium, a second base can be useful to precipitate the metal salt to effect metal salt loading onto the carbonaceous substrate. A combination of lignin and the first base and a water-soluble lignin derivative can also be used.

The second base and any first base can be the same or different. Suitable examples of the second base include an ammonia, carbonate, bicarbonate, or hydroxide base. Specific examples include sodium hydroxide, ammonium bicarbonate, and potassium hydroxide. In one aspect, the first base when it is used with lignin can be a hydroxide base such as sodium or potassium hydroxide and the second base used in the metal salt loading step can be an ammonia base such as ammonium bicarbonate.

A variety of metal salts can be used as precursors to the metal oxide which can form upon calcining the carbonaceous substrate once it is loaded with the metal salt. In one aspect, the metal salt is a d-block transition metal salt. In a further aspect, the metal salt is ferrous. In another aspect, the metal salt is non-ferrous. In a further aspect, the metal salt is a salt of iron, nickel, molybdenum, copper, or cobalt. A metal salt having any suitable anion is contemplated. In one aspect, the metal salt is a transition metal nitrate, a transition metal acetate, a transition metal citrate, a transition metal chloride, or any hydrate or combination of these salts.

In one aspect, forming catalytic sites on the carbonaceous substrate from the metal salt comprises converting the metal salt to a metal oxide followed by reducing the metal oxide to its corresponding elemental metal. Thus, the term “catalyzed carbonaceous substrate” refers to a carbon-based substrate having catalyst formed or deposited on the substrate.

In one specific aspect, for example, the method comprises: (a) dispersing a carbonaceous substrate in a medium comprising water and one or more of: (i) lignin and a first base: or (ii) a water-soluble lignin derivative: (b) contacting the medium with a metal salt and a second base: (c) obtaining a solid from the medium, the solid comprising the carbonaceous substrate having the metal salt loaded thereon: (d) calcining the solid to convert the metal salt to a metal oxide: (e) reducing the metal oxide to its corresponding elemental metal to form a catalyzed carbonaceous substrate; and (f) exposing the catalyzed carbonaceous substrate to a carbon-containing gas to grow carbon nanotubes on the catalyzed carbonaceous substrate. The dispersion, as described above, can be free of organic solvent, free of non-lignin derived surfactants, or free of both.

In one aspect, calcining can be performed at a temperature ranging from 400° C. to 650° C. “Calcining” refers to thermal treatment of the solid whereby the solid is raised to high temperature without melting to convert the metal salt to a metal oxide. In a further aspect, prior to calcining, the solid can be obtained from the medium by filtering the solid from the medium, washing the solid, and drying the solid at a temperature less than 100° C., followed by the calcining step. In a further aspect, the metal oxide can be reduced to its corresponding elemental metal using hydrogen gas. In a further aspect, the catalyzed carbonaceous substrate can be exposed to the carbon-containing gas at a temperature ranging from 600° C. to 1200° C., e.g., 600° C. to 1000° C., 600° C. to 800° C., or in one specific aspect, about 700° C. In general, the disclosed process can be performed with any suitable reactor, for example a fluidized bed reactor, rotating reactor, or tube reactor.

A variety of carbon-containing gases and mixtures thereof are contemplated. The carbon-containing gas for example can comprise carbon monoxide, ethylene, acetylene, methane, benzene, xylene, carbon dioxide or a combination thereof. Other co-gases can be used with any carbon-containing gas such as hydrogen, nitrogen, and the like. One non-limiting example of a carbon-containing gas is ethylene, hydrogen, and nitrogen, which can be used for example in a 10:10:80 volume % ratio (ethylene:H₂:N₂). Another example of a carbon-containing gas is carbon monoxide, hydrogen, and nitrogen, which can be used for example in a 40:40:20 volume % ratio (CO:H₂:N₂).

In some aspects, the % yield of carbon nanotubes formed on the carbonaceous substrate can be in the range of about 100-500% by weight of the carbonaceous substrate.

Also described are carbon nanotube hybrid materials made by any embodiments of the disclosed method.

A further advantage of the described method is that in some aspects, the method does not require the use of a non-catalytic material at any step of the process, including for example during the step that involves carbon nanotube growth. It was found that the described method allows for thin and uniform growth of carbon nanotubes on carbonaceous substrates without the need for a non-catalytic material being deposited on the carbonaceous substrate in addition to the metal oxide that is ultimately reduced to the corresponding metal to form the catalyzed carbonaceous substrate. In other words, it was observed that any interaction between the catalyst sites with the carbonaceous substrate itself did not interfere with carbon nanotube growth. Specific non-catalytic materials that can be excluded from the process include aluminum, aluminum salts, hydrate of aluminum salts, glasses, silicates, silanes, and the like.

Similarly, the disclosed method does not require a polymer coating on the carbonaceous substrate prior to forming the carbon nanotubes on the substrate. For example, a barrier coating of a polymer of furfuryl alcohol on the carbonaceous substrate is not required.

### EXEMPLARY ASPECTS

The following exemplary aspects of the disclosure, while non-limiting, are specifically contemplated.
Aspect (1): A method for making a carbon nanotube hybrid material, the method comprising: (a) dispersing a carbonaceous substrate in a medium comprising water and one or more of: (i) lignin and a first base; or (ii) a water-soluble lignin derivative: wherein the medium is free of organic solvent and non-lignin derived surfactants: (b) contacting the medium with a metal salt and a second base; (c) forming catalytic sites on the carbonaceous substrate from the metal salt to provide a catalyzed carbonaceous substrate; and (d) exposing the catalyzed carbonaceous substrate to a carbon-containing gas to grow carbon nanotubes on the catalyzed carbonaceous substrate.
Aspect (2): The method of Aspect (1), wherein the carbonaceous substrate comprises natural graphite, synthetic graphite, graphene, carbon black, carbon fiber, or activated carbon.
Aspect (3): The method of any preceding Aspect, wherein the first base provides a medium pH ranging from 8 to 12.
Aspect (4): The method of any preceding Aspect, wherein the first base is an ammonia, carbonate, bicarbonate, or hydroxide base.
Aspect (5): The method of any preceding Aspect, wherein the first base is sodium hydroxide.
Aspect (6): The method of any preceding Aspect, wherein the second base is an ammonia, carbonate, bicarbonate, or hydroxide base.
Aspect (7): The method of any preceding Aspect, wherein the second base is sodium hydroxide.
Aspect (8): The method of any preceding Aspect, wherein the second base is ammonium bicarbonate.
Aspect (9): The method of any preceding Aspect, wherein the water-soluble lignin derivative is an anionic lignin derivative.
Aspect (10): The method of any preceding Aspect, wherein the water-soluble lignin derivative is lignosulfonate.
Aspect (11): The method of any preceding Aspect, wherein the metal salt is a d-block transition metal salt.
Aspect (12): The method of any preceding Aspect, wherein the metal salt is ferrous or non-ferrous.
Aspect (13): The method of any preceding Aspect, wherein the metal salt is a salt of iron, nickel, molybdenum, or cobalt or combinations thereof.
Aspect (14): The method of any preceding Aspect, wherein forming catalytic sites on the carbonaceous substrate from the metal salt comprises converting the metal salt to a metal oxide followed by reducing the metal oxide to its corresponding elemental metal.
Aspect (15): The method of any preceding Aspect, wherein the carbon-containing gas comprises ethylene, acetylene, methane, benzene, xylene, carbon dioxide, or a combination thereof.
Aspect (16): A carbon nanotube hybrid material made by the method of any preceding Aspect.
Aspect (17): A method for making a carbon nanotube hybrid material, the method comprising: (a) dispersing a carbonaceous substrate in a medium comprising water and one or more of: (i) lignin and a first base; or (ii) a water-soluble lignin derivative: (b) contacting the medium with a metal salt and a second base; (c) obtaining a solid from the medium, the solid comprising the carbonaceous substrate having the metal salt loaded thereon: (d) calcining the solid to convert the metal salt to a metal oxide: (e) reducing the metal oxide to its corresponding elemental metal to form a catalyzed carbonaceous substrate; and (f) exposing the catalyzed carbonaceous substrate to a carbon-containing gas to grow carbon nanotubes on the catalyzed carbonaceous substrate.
Aspect (18): The method of Aspect (17), wherein the dispersion is free of organic solvent.
Aspect (19): The method of Aspect (17) or (18), wherein the dispersion is free of non-lignin derived surfactants.
Aspect (20): The method of any of Aspects (17)-(19), wherein the carbonaceous substrate comprises natural graphite, synthetic graphite, graphene, carbon black, carbon fiber, or activated carbon.
Aspect (21): The method of any of Aspects (17)-(20), wherein the first base provides a medium pH ranging from 8 to 12.
Aspect (22): The method of any of Aspects (17)-(21), wherein the first base is an ammonia, carbonate, bicarbonate, hydroxide base.
Aspect (23): The method of any of Aspects (17)-(22), wherein the first base is sodium hydroxide.
Aspect (24): The method of any of Aspects (17)-(23), wherein the second base is an ammonia, carbonate, bicarbonate, or hydroxide base.
Aspect (25): The method of any of Aspects (17)-(24), wherein the second base is sodium hydroxide.
Aspect (26): The method of any of Aspects (17)-(25), wherein the second base is ammonium bicarbonate.
Aspect (27): The method of any of Aspects (17)-(26), wherein the water-soluble lignin derivative is an anionic lignin derivative.
Aspect (28): The method of any of Aspects (17)-(27), wherein the water-soluble lignin derivative is lignosulfonate.
Aspect (29): The method of any of Aspects (17)-(28), wherein the metal salt is a d-block transition metal salt.
Aspect (30): The method of any of Aspects (17)-(29), wherein the metal salt is non-ferrous.
Aspect (31): The method of any of Aspects (17)-(30), wherein the metal salt is a salt of nickel, molybdenum, or cobalt or combinations thereof.
Aspect (32): The method of any of Aspects (17)-(31), wherein calcining is performed at a temperature ranging from 400° C. to 650° C.
Aspect (33): The method of any of Aspects (17)-(32), wherein the solid is obtained from the medium by filtering the solid from the medium, washing the solid, and drying the solid at a temperature less than 100° C.
Aspect (34): The method of any of Aspects (17)-(33), wherein the metal oxide is reduced to its corresponding elemental metal using hydrogen gas.
Aspect (35): The method of any of Aspects (17)-(34), wherein the catalyzed carbonaceous substrate is exposed to the carbon-containing gas at a temperature ranging from 600° C. to 1200° C.
Aspect (36): The method of any of Aspects (17)-(35), wherein the carbon-containing gas comprises ethylene, acetylene, methane, benzene, xylene, carbon dioxide, or a combination thereof.
Aspect (37): A carbon nanotube hybrid material made by the method of any preceding Aspect.

### EXAMPLES

The following examples further illustrate this disclosure. The scope of the disclosure and claims is not limited by the scope of the following examples.

### Example 1

An exemplary carbon nanotube hybrid material was made according to the following method. Lignin was dissolved in alkaline aqueous medium (0.0032M NaOH, i.e., the first base), and carbon black was added. The mixture was stirred to disperse the carbon black in the medium. Nickel metal salt (Ni(NO₃)₂) was added drop wise along with an alkali source, in this case NH₄HCO₃, i.e., the second base. The resulting mixture was stirred at 80° C. for three hours. The solid carbon black substrate having the Ni metal salt loaded onto the substrate was then filtered from the aqueous medium and washed to remove impurities including remaining lignin and lignin derivatives. The solid was dried at 80° C. under vacuum for 12 hours or without vacuum at 80° C. for 24 hours.

To prepare the catalyzed substrate, the dried solid was calcined under a nitrogen atmosphere at 600° C. for four hours. The resulting catalyzed substrate was then heated under a nitrogen atmosphere. Once the furnace temperature reached 700° C., carbon monoxide and hydrogen gas was passed through the furnace while keeping the furnace temperature at 680° C.-1200° C. for a time ranging from 10 min-3 h. Heating was switched off, the substrate was cooled under a nitrogen atmosphere, and the resulting carbon nanotube-carbon black hybrid substrate was collected. The % yield of CNT formation was found to be 264% by weight of the carbonaceous substrate.

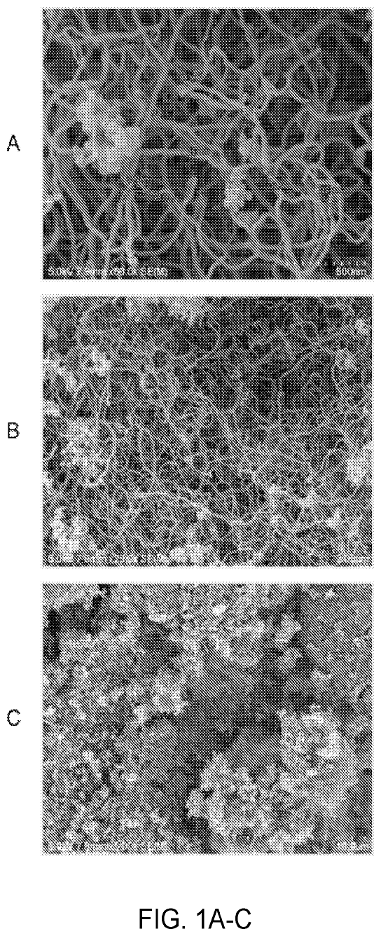

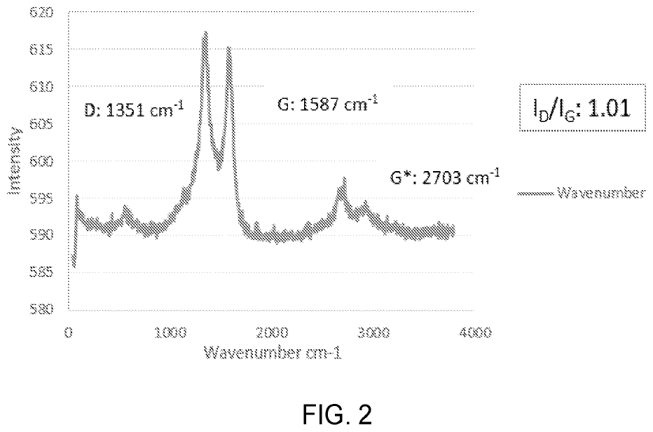

The specific carbon black substrate used was Raven PFEB (Birla Carbon, Marietta GA, USA). The nickel catalyst loading on the substrate was determined to be 18.24% by weight of the substrate. SEM images of the hybrid material are shown in FIGS. 1A-C (A: 500 nm scale, B: 2 μm scale, C: 10 μm scale), demonstrating that uniform and thin carbon nanotubes were grown on the carbon black, which appear in the SEM images as grape-like clusters. The Raman spectra for the hybrid material is shown in FIG. 2.

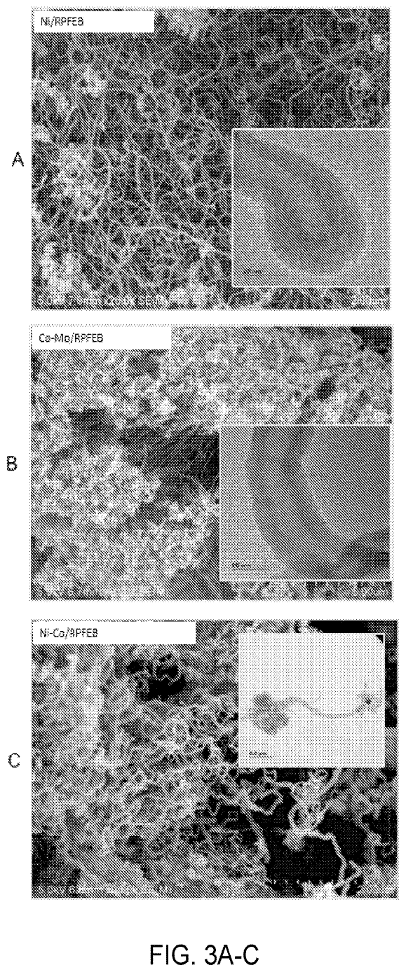

Additional metal catalysts were also evaluated with yields shown in Table 1. Corresponding SEM/HRTEM images of the Ni-Raven PFEB hybrid, Ni—Co/Raven PFEB hybrid, and Co—Mo/Raven PFEB hybrid are shown in FIG. 3A (2 μm scale), 3B (5 μm scale), and 3C (2 μm scale), respectively.

TABLE 1

| | % CNT Yield by Weight of |
|---|---|
| Catalyst | Substrate |
| Ni on Raven PFEB | 100 |
| Ni—Co on Raven PFEB | 209 |
| Co—Mo on Raven PFEB | 486 |

### Example 2

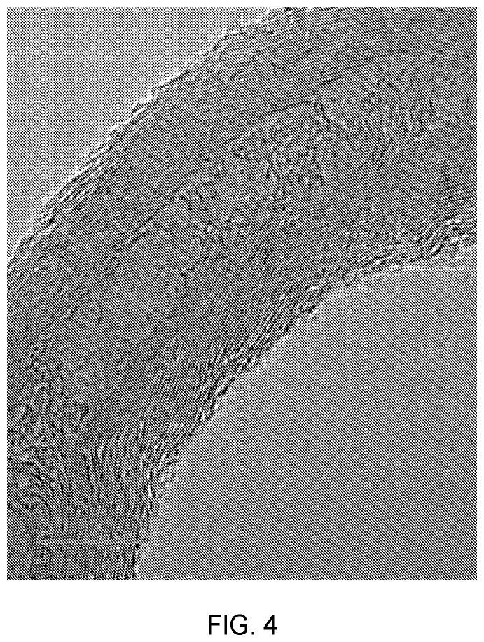

In this example, ethylene was used as the carbon source. The catalyzed substrate prepared as described above was heated under a nitrogen atmosphere. Once the furnace temperature reached 700° C., ethylene, hydrogen and nitrogen gas (10:10:80 volume %) was passed through the furnace while keeping the furnace temperature at 700° C. for a time ranging from 30 min-3 h. Heating was switched off, the substrate was cooled under a nitrogen atmosphere, and the resulting carbon nanotube-carbon black hybrid substrate was collected. The % yield of carbonaceous material was found to be in the range of 300-500%. The resulting TEM image is shown in FIG. 4.

### Example 3

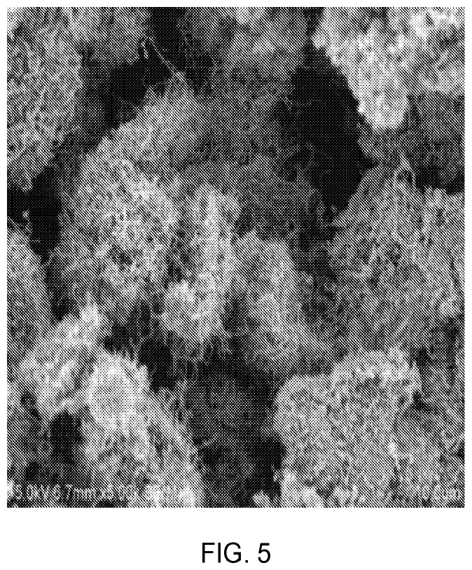

In this example, graphite was used as the catalyst support. Ni was deposited on a graphite support in a similar manner as described earlier using the lignin co-precipitation process. The catalyzed substrate was heated under a nitrogen atmosphere. Once the furnace temperature reached 700° C. carbon monoxide, hydrogen, and nitrogen gas (40:40:20 volume %) was passed through the furnace while keeping the furnace temperature at 700° C. for a time of 3 h. Heating was switched off, the substrate was cooled under a nitrogen atmosphere, and the resulting carbon nanotube-carbon black hybrid substrate was collected. The % yield of carbonaceous material was found to be in the range of 300-500%. The resulting SEM image is shown in FIG. 5.

### Example 4

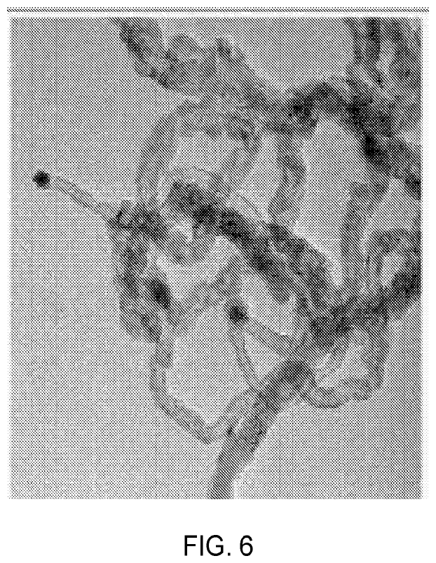

In this example, water soluble lignin derivative was used to disperse carbon black, Raven PFEB in aqueous medium. Catalyst deposition was done in similar way as described in earlier examples. The catalyzed substrate was heated under a nitrogen atmosphere. Once the furnace temperature reached 700° C., ethylene, hydrogen, and nitrogen gas (10:10:80 volume %) was passed through the furnace while keeping the furnace temperature at 700° C. for 3 h. Heating was switched off, the substrate was cooled under a nitrogen atmosphere, and the resulting carbon nanotube-carbon black hybrid substrate was collected. The % yield of carbonaceous material was found to be in the range of 100-200%. The resulting TEM image is shown in FIG. 6.

Features and advantages of this disclosure are apparent from the detailed specification, and the claims cover all such features and advantages. Numerous variations will occur to those skilled in the art, and any variations equivalent to those described in this disclosure fall within the scope of this disclosure. Those skilled in the art will appreciate that the conception upon which this disclosure is based may be used as a basis for designing other methods and systems for carrying out the several purposes of this disclosure. As a result, the claims should not be considered as limited by the description or examples.

What is claimed is:

1. A method for making a carbon nanotube hybrid material, the method comprising:
a) dispersing a carbonaceous substrate in a medium comprising water and one or more of:
i) lignin and a first base: or
ii) a water-soluble lignin derivative:
wherein the medium is free of organic solvent and non-lignin derived surfactants:
b) contacting the medium with a metal salt and a second base:
c) forming catalytic sites on the carbonaceous substrate from the metal salt to provide a catalyzed carbonaceous substrate; and
d) exposing the catalyzed carbonaceous substrate to a carbon-containing gas to grow carbon nanotubes on the catalyzed carbonaceous substrate.

2. The method of claim 1, wherein the carbonaceous substrate comprises natural graphite, synthetic graphite, graphene, carbon black, carbon fiber, or activated carbon.

3. The method of claim 1, wherein the first base provides a medium pH ranging from 8 to 12.

4. The method of claim 1, wherein the first base is an ammonia, carbonate, bicarbonate, or hydroxide base.

5. The method of claim 1, wherein the first base is sodium hydroxide.

6. The method of claim 1, wherein the second base is an ammonia, carbonate, bicarbonate, or hydroxide base.

7. The method of claim 1, wherein the second base is sodium hydroxide.

8. The method of claim 1, wherein the second base is ammonium bicarbonate.

9. The method of claim 1, wherein the water-soluble lignin derivative is an anionic lignin derivative.

10. The method of claim 1, wherein the water-soluble lignin derivative is lignosulfonate.

11. The method of claim 1, wherein the metal salt is a d-block transition metal salt.

12. The method of claim 1, wherein the metal salt is ferrous or non-ferrous.

13. The method of claim 1, wherein the metal salt is a salt of iron, nickel, molybdenum, or cobalt or combinations thereof.

14. The method of claim 1, wherein forming catalytic sites on the carbonaceous substrate from the metal salt comprises converting the metal salt to a metal oxide followed by reducing the metal oxide to its corresponding elemental metal.

15. The method of claim 1, wherein the carbon-containing gas comprises ethylene, acetylene, methane, benzene, xylene, carbon dioxide, or a combination thereof.

16. A carbon nanotube hybrid material made by the method of claim 1.

17. A method for making a carbon nanotube hybrid material, the method comprising:
a) dispersing a carbonaceous substrate in a medium comprising water and one or more of:
i) lignin and a first base: or
ii) a water-soluble lignin derivative:
b) contacting the medium with a metal salt and a second base:
c) obtaining a solid from the medium, the solid comprising the carbonaceous substrate having the metal salt loaded thereon;
d) calcining the solid to convert the metal salt to a metal oxide:
e) reducing the metal oxide to its corresponding elemental metal to form a catalyzed carbonaceous substrate; and
f) exposing the catalyzed carbonaceous substrate to a carbon-containing gas to grow carbon nanotubes on the catalyzed carbonaceous substrate.

18. The method of claim 17, wherein the dispersion is free of organic solvent.

19. The method of claim 17, wherein the dispersion is free of non-lignin derived surfactants.

20. The method of claim 17, wherein the carbonaceous substrate comprises natural graphite, synthetic graphite, graphene, carbon black, carbon fiber, or activated carbon.

21-37. (canceled)
